(19) United States
(12) Patent Application Publication
(10) Pub. No.: US 2012/0176787 A1
(43) Pub. Date: Jul. 12, 2012

(54) METHOD OF MAKING HIGH COLOR RENDERING (CRI) LED LIGHTS AND HIGH COLOR RENDERING INDEX LED LIGHTS

(76) Inventor: William Yu, Laytonsville, MD (US)

(21) Appl. No.: 13/347,421

(22) Filed: Jan. 10, 2012

Related U.S. Application Data
(60) Provisional application No. 61/431,324, filed on Jan. 10, 2011.

(51) Int. Cl. F21V 9/16; H05K 13/00

(52) U.S. Cl. 362/231; 29/592.1

(57) ABSTRACT

A high color rendering index light and method of forming the same wherein the light is formed from at least two light emitting diodes each having color temperatures which are close enough to one another to be visually the same and which are connected in series and wherein each of which has a different color rendering index and wherein at least one of the at least two light emitting diodes has a high Color Rendering Index Value of at least Ra 80.

### CROSS-REFERENCE TO RELATED APPLICATIONS

This application is a non-provisional application claiming the benefit of U.S. Provisional Patent Application Ser. No. 61/431,324, filed Jan. 10, 2011, in the name of the same inventor. The entire application is incorporated herein by reference.

### BACKGROUND OF THE INVENTION

1. Field Of The Invention

This invention if directed to the field of light emitting diodes (LEDs) and more specifically to a method for making a light emitting diode (LED)light with a target color temperature, a high color rendering index (CRI), and high overall lumen efficacy high color rendering index LED light.

2. Brief Description Of The Related Art

Solid State electronic devices which convert electricity into light are known as light emitting diodes (LEDs). Each LED includes at least one layer, and often several layers, of semi-conducting material placed intermediate oppositely doped layers to which an electrical charge is applied to thereby cause light to be emitted from the semi-conducting material layer. The LEDs may be single or multiple chip structures. Multiple chip structures use combinations of generally red, green and blue LEDs which are combined to emit light through a lens. In order to obtain a white light source for general illumination of areas both inside and out, the intensity of each color in the combination is adjusted. In order to obtain a white light source using single chip LEDs, the LED is coated with one or more phosphors. By way of example, a blue light emitting LED may be coated with a yellow phosphor so that the yellow phosphor generate a white light. By varying the intensity of the blue LED and the concentration of the yellow phosphor, varying intensities of white light illumination can be achieved. That is, the luminous efficacy of the light may be increase. A further variation to the multiple chip LEDs is the use of phosphor coating with combination with the various colored LEDs. It should be noted that the coatings may be applied directly to a base LED, on only portions of the LED or on lenses or layers over the LED.

In the lighting industry, light sources that produce high color rendering indexes (CRI) are frequently desired because the light is considered more vibrant when reflected from an illuminated surface. The light sources having high CRI are those in the white light range. The color rendering index is a quantitative measure of the ability of a light to reproduce an actual color of an object when compared to how the object appears in natural light. LED Lights having the best similarity to a reference light have an CRI Ra equal to 100, while lights having the poorest similarity to a reference light have a CRI Ra equal to zero.

Another factor considered in the lighting industry which is considered when evaluating a LED light source is the color temperature of the LED. Higher color temperatures are affiliated with purer more cool bright white or bluish light sources, 4000K and greater, whereas lower color temperatures, below 4000K, are considered as warmer more yellowish light sources.

Generally, in combining LED and phosphors to obtain higher color temperatures, many manufacturers mix LEDs of very different color temperatures or wavelengths. Also, many manufacturers must use secondary optics to mix the various light colors to obtain a white light output.

Some examples of prior art methods of creating LEDs for lighting applications are described in US Published Applications 2010/0096974 to Setlur et al, 2101/0090935 to Tseng et al, 2010/0118510 to Bailey et al, 2010/0002440 to Negley et al, 2009/0152571 to Su et al, 2010/0045154 to Kim et al, 2010/0025700 to Jung, and 2009/0095966 to Keller et al.

### SUMMARY OR THE INVENTION

In accordance with the method of the present invention this method, color temperature generally refers to a white light, though non-white colors are encompassed as well, and the high CRI of the LED light means the Ra value, General Color Rendering Index, of the light is greater then 80 and R9 value, special rendering value, of the light is greater than 0.

The method combines at least two types of LEDs of substantially the same color temperatures and different CRI and different lumen efficacies.

The color temperatures of the at least two types of LEDs are selected such that the difference in color temperatures between the types is (a) barely noticeable to the human eye, and (b) within +/−10% of the target color temperature. In other words, rather than comparing to a target color temperature, the color temperature of one type is compared to the color temperature of another type, and the difference in color temperature between the types is barely noticeable to the human eye.

It is a primary object of the present invention to obtain an extremely good white light LED structure having a high coloring Index (CRI) without the need for use of additional mixing covers or lenses and wherein at least two colors are of substantially the same color temperature.

### DESCRIPTION OF THE PREFERRED EMBODIMENT

In accordance with the present invention this method, color temperatures generally refer to those of white light, although non-white colors are encompassed as well. Further, the method is directed to High Color Rendering Indexes (CRI) of LED lights wherein an Ra value, general Color Rendering Index Value, of the light is greater then 80 and R9 value, special rendering value, of the light is greater than 0. The method combines at least two types of such LEDs of substantially the same color temperatures and different CRI and different lumen efficacies.

The color temperatures of the at least two types of LEDs are selected such that the difference in color temperatures between the types is barely noticeable to the human eye, and is within +/−10% of a target color temperature. In other words, rather than comparing to a target color temperature, the color temperature of one type is compared to the color temperature of another type, and the difference in color temperature between the types is barely noticeable to the human eye.

To illustrate the proper selection of color temperatures, the following lists an exemplary range of target color temperatures, in Kelvin (K) along with the corresponding difference in color temperatures that is acceptable for use in the method of this invention:

2700-3000K/(+/−) 50K

3000-4000K/(+/−) 60K

4000-5000K/(+/−) 75K

5000-6500K/(+/−) 100K

6500-9000K/(+/−) 150K

Based on this information, a target color temperature of 4500K may be a combination of at least two types of LEDs, where the difference in color temperatures between the at least two types of LEDs is 75K or less (e.g. |K1-K2|=75K). That is, suppose K1, target light color of a first LED is 4500K, a second LED must have a color temperature within 75K of 4500K or 4575K or 4425K. A target color temperature in a 7500K range requires at that the LEDs be within 150K from one anther whereas a target color temperature of 6000K requires that the LEDs be within 100K from one another. In like manner, a target color temperature of 3500K requires the LEDs to be within 60K from one another while a target color temperature of 2900K requires that the LEDs be within 50K from one another.

The CRI and lumen efficacy are selected such that at least one of the at least two types of LEDs has a high CRI, and at least one of the at least two types of LEDs has a high lumen efficacy, such as white LED lights or better, resulting in the combined light having a high CRI and high lumen efficacy.

For example, to make a light with a target color temperature of 2800K with high CRI and high lumen efficacy, a first type of LED with a first color temperature of minimally 2775K and a high CRI value and low lumen efficacy is combined with a second type of LED with a second color temperature of maximally 2825K and a low CRI value and high lumen efficacy. The difference between the first and second color temperatures is not noticeable to the human eye, and the first and second CRI and lumen efficacy values are different.

The at least two types of LEDs can be arranged in an array at certain predetermined ratios , e.g. X number of a first type of LED to a Y number of a second type of LED. The arrangement of the array and orientation of each LED in the array can further be made in a predetermined manner to achieve the target color temperature. The LEDs are mounted to an array support and connected in series and driven by the same current to maintain the same power ratio under operating conditions. A higher overall power output of such an LED light could be achieved by driving multiple groups of the LED arrays, which are connected in parallel.

With regard to lumen efficacy, since the combination of the at least two types of LEDs already produces a light with a target color temperature and high CRI, there is no need for any optical filter between the light exiting the LEDs and a user of the light. An optical filter absorbs energy and reduces the overall lumen efficacy of a light. Therefore, the absence of an optical filter in this method results in a higher overall lumen efficacy.

The LEDs could be made using a blue LED chip coated with a yellow phosphor; or the combination of yellow, green and red phosphor; or using the combination of red and blue LED chips in the same LED package and coated with a yellow phosphor; or the combination of yellow and green phosphor.

The foregoing description of the preferred embodiment of the invention has been presented to illustrate the principles of the invention and not to limit the invention to the particular embodiment illustrated. It is intended that the scope of the invention be defined by all of the embodiments encompassed within the following claims and their equivalents.

I claim:

1. A method of forming a high color rendering index light emitting diode light consisting of at least two light emitting diodes, the method comprising the steps of:
A. Selecting at least two light emitting diodes having color temperatures which are close enough to one another to be visually the same and wherein each of which has a different color rendering index and lumen efficacy, and wherein at least one of the at least two light emitting diodes has a high Color Rendering Index Value of at least Ra 80, and at least one of the at least two types of LEDs has a high lumen efficacy, and
B. Connecting the at least two light emitting diodes in electrical series.

2. The method of claim 1 wherein the two light emitting diodes are selected having color temperatures between 2700K and 3000K and wherein the two light emitting diodes are within 50K of one another.

3. The method of claim 1 wherein the two light emitting diodes are selected having color temperatures between 3000K to 4000K and wherein the two light emitting diodes are within 60K of one another.

4. The method of claim 1 wherein the two light emitting diodes are selected having color temperatures between 4000K to 5000K and wherein the two light emitting diodes are within 75K of one another.

5. The method of claim 1 wherein the two light emitting diodes are selected having color temperatures between 5000K to 6500K and wherein the two light emitting diodes are within 100K of one another.

6. The method of claim 1 wherein the two light emitting diodes are selected having color temperatures between 6500K to 9000K and wherein the two light emitting diodes are within 150K of one another.

7. The method of claim 1 wherein the two light emitting diodes are blue LED chips and coating the blue LED chips with at least a yellow phosphor.

8. The method of claim 7 including coating the LED chips with a combination of yellow, green and red phosphors.

9. The method of claim 1 wherein the two light emitting diodes are each a combination of red and blue LED chips in a common same LED package and coating the LED packages with at least a yellow phosphor.

10. The method of claim 9 including coating the LED packages with a combination of yellow and green phosphors.

11. A high color rendering index light comprising; at least two light emitting diodes each having color temperatures which are close enough to one another to be visually the same and wherein each of which has a different color rendering index and lumen efficacy, and wherein at least one of the at least two light emitting diodes has a high Color Rendering Index Value of at least Ra 80, and at least one of the at least two types of LEDs has a high lumen efficacy, and the at least two light emitting diodes being connected in electrical series to one another.

12. The high color rendering index light of claim 11 wherein the two light emitting diodes are selected having color temperatures between 2700K and 3000K and wherein the two light emitting diodes are within 50K of one another.

13. The high color rendering index light of claim 11 wherein the two light emitting diodes are selected having color temperatures between 3000K to 4000K and wherein the two light emitting diodes are within 60K of one another.

14. The high color rendering index light of claim 11 wherein the two light emitting diodes are selected having color temperatures between 4000K to 5000K and wherein the two light emitting diodes are within 75K of one another.

15. The high color rendering index light of claim 11 wherein the two light emitting diodes are selected having color temperatures between 5000K to 6500K and wherein the two light emitting diodes are within 100K of one another.

16. The high color rendering index light of claim 11 wherein the two light emitting diodes are selected having color temperatures between 6500K to 9000K and wherein the two light emitting diodes are within 150K of one another.

17. The high color rendering index light of claim 11 wherein the two light emitting diodes are blue LED chips coated with at least a yellow phosphor.

18. The high color rendering index light of claim 17 wherein the LED chips are coated with a combination of yellow, green and red phosphors.

19. The high color rendering index light of claim 11 wherein the two light emitting diodes are each a combination of red and blue LED chips in a common same LED package, and wherein each package is coated with at least a yellow phosphor.

20. The high color rendering index light of claim 19 wherein each of the LED packages are coated with a combination of yellow and green phosphors.
